(19) United States
(12) Patent Application Publication
(10) Pub. No.: US 2025/0149978 A1
(43) Pub. Date: May 8, 2025

(54) POWER SUPPLY CIRCUIT AND DISPLAY DEVICE INCLUDING THE SAME

(71) Applicant: LG Display Co., Ltd., Seoul (KR)

(72) Inventors: Hoon JANG, Paju-si (KR); Sang Uk LEE, Paju-si (KR)

(21) Appl. No.: 18/911,455

(22) Filed: Oct. 10, 2024

(30) Foreign Application Priority Data
Nov. 8, 2023 (KR) 10-2023-0153735

(51) Int. Cl. H02M 1/38; G09G 3/32; G09G 3/3266; H02M 3/157; H02M 3/158; H03K 19/20

(52) U.S. Cl. CPC H02M 1/38; G09G 3/32; G09G 3/3266; H02M 3/157; H02M 3/158; G09G 2300/0408; G09G 2330/021; H03K 19/20

(57) ABSTRACT

A display apparatus includes a display panel configured to display an image, a panel driver configured to drive the display panel, and a power supply including an output circuit, including a first switch and a second switch configured to charge or discharge power input through an input terminal thereof to output through an output terminal thereof, and an output controller including a driving circuit configured to control charging or discharging of the output circuit, for supplying power to the display panel, wherein the driving circuit senses an LX node voltage of the output circuit to determine whether at least one of a first body diode included in the first switch and a second body diode included in the second switch is turned on or not, and based thereon, controls a dead time corresponding to one of the first switch and the second switch.

### CROSS-REFERENCE TO RELATED APPLICATIONS

This application claims the benefit of the Korean Patent Application No. 10-2023-0153735 filed on Nov. 8, 2023, which is hereby incorporated by reference as if fully set forth herein.

### BACKGROUND

### Technical Field

The present disclosure relates to a power supply and a display apparatus including the same.

### Description of the Related Art

As information technology advances, the market for display apparatuses which are connection mediums connecting a user with information is growing. Therefore, the use of display apparatuses such as light emitting display apparatuses, quantum dot display (QDD) apparatuses, and liquid crystal display (LCD) apparatuses is increasing.

The display apparatuses described above include a display panel which includes a plurality of subpixels, a driver which outputs a driving signal for driving the display panel, and a power supply which generates power which is to be supplied to the display panel or the driver.

In such display apparatuses, when the driving signal (for example, a gate signal and a data signal) is supplied to each of the subpixels provided in the display panel, a selected subpixel may transmit light or may self-emit light, and thus, an image may be displayed.

### BRIEF SUMMARY

The present disclosure may provide a power supply and a display apparatus including the same, which may improve power consumption and may reduce a dead time for which a switching operation is not performed, thereby stably and efficiently generating power. Also, the present disclosure may provide a power supply and a display apparatus including the same, which may allow a normal switching operation to be performed despite a zero current condition where a current does not flow, based on the control of a dead time, thereby maintaining the stability of driving.

In accordance with the disclosure, as embodied and broadly described herein, a display apparatus includes a display panel configured to display an image, a panel driver configured to drive the display panel, and a power supply including an output circuit, including a first switch and a second switch configured to charge or discharge power input through an input terminal thereof to output through an output terminal thereof, and an output controller including a driving circuit configured to control charging or discharging of the output circuit, for supplying power to the display panel, wherein the driving circuit senses an LX node voltage of the output circuit to determine whether at least one of a first body diode included in the first switch and a second body diode included in the second switch is turned on or not, and based thereon, controls a dead time corresponding to one of the first switch and the second switch.

The driving circuit may include a dead time controller configured to control the dead time corresponding to one of the first switch and the second switch, based on the LX node voltage sensed from the output circuit, a reference voltage, and a switch control reference signal output from a control circuit of the driving circuit.

The dead time controller may include a first body diode sensing circuit configured to output a first sensing result value corresponding to a turn-on time of the first body diode, a second body diode sensing circuit configured to output a second sensing result value corresponding to a turn-on time of the second body diode, a first AND gate configured to output a first AND operation value, based on a signal for determining the turn-on/off of the first body diode and a second switch control reference signal output from the control circuit of the driving circuit, a second AND gate configured to output a second AND operation value, based on a signal for determining the turn-on/off of the second body diode and a first switch control reference signal output from the control circuit of the driving circuit, a third AND gate configured to output a third AND operation value, based on a signal for determining the turn-on/off of the second body diode and the second switch control reference signal output from the control circuit of the driving circuit, a first OR gate configured to output a first OR operation value, based on the first AND operation value output from the first AND gate and the third AND operation value output from the third AND gate, a counter circuit configured to output a counter result value for determining whether there is a time corresponding to a zero current, based on a signal for controlling the first switch and the second switch, a delay circuit configured to delay, for a certain time, the counter result value output from the counter circuit to output a delayed counter result value, and a second OR gate configured to output a second OR operation value, based on the second AND operation value output from the second AND gate and a delay value output from the delay circuit connected to an output terminal of the counter circuit.

The dead time controller may include a first body diode sensing circuit including an inverting terminal connected to the LX node of the output circuit and a noninverting terminal connected to a first reference voltage terminal, a second body diode sensing circuit including an inverting terminal connected to the LX node of the output circuit and a noninverting terminal connected to a second reference voltage terminal, a first AND gate including a first input terminal connected to an output terminal of the first body diode sensing circuit and a second input terminal connected to a control circuit of the driving circuit, a second AND gate including a first input terminal connected to an output terminal of the second body diode sensing circuit and a second input terminal connected to the control circuit of the driving circuit, a third AND gate including a first input terminal connected to an output terminal of the second AND gate and a second input terminal connected to the control circuit of the driving circuit, a first OR gate including a first input terminal connected to an output terminal of the first AND gate and a second input terminal connected to an output terminal of the third AND gate, a counter circuit including a first input terminal connected to an output terminal of the first OR gate and a second input terminal connected to an output terminal of the second OR gate, and a second OR gate including a first input terminal connected to an output terminal of the second AND gate and a second input terminal connected to the delay circuit connected to an output terminal of the counter circuit.

The dead time controller may include a first body diode sensing circuit configured to output a first sensing result value corresponding to a turn-on time of the first body diode, a second body diode sensing circuit configured to output a second sensing result value corresponding to a turn-on time of the second body diode, a first AND gate configured to output a first AND operation value, based on a signal for determining the turn-on/off of the first body diode and a second switch control reference signal output from the control circuit of the driving circuit, a second AND gate configured to output a second AND operation value, based on a signal for determining the turn-on/off of the second body diode and a first switch control reference signal output from the control circuit of the driving circuit, a third AND gate configured to output a third AND operation value, based on a signal for determining the turn-on/off of the second body diode and the second switch control reference signal output from the control circuit of the driving circuit, a counter circuit configured to output a counter result value for determining whether there is a time corresponding to a zero current, based on a signal for controlling the first switch and the second switch, a delay circuit configured to delay, for a certain time, the counter result value output from the counter circuit to output a delayed counter result value, and a first OR gate configured to output a first OR operation value, based on the first AND operation value output from the first AND gate, the third AND operation value output from the third AND gate, and a delay value output from the delay circuit connected to an output terminal of the counter circuit.

The dead time controller may include a first body diode sensing circuit including an inverting terminal connected to the LX node of the output circuit and a noninverting terminal connected to a first reference voltage terminal, a second body diode sensing circuit including an inverting terminal connected to the LX node of the output circuit and a noninverting terminal connected to a second reference voltage terminal, a first AND gate including a first input terminal connected to an output terminal of the first body diode sensing circuit and a second input terminal connected to a control circuit of the driving circuit, a second AND gate including a first input terminal connected to an output terminal of the second body diode sensing circuit and a second input terminal connected to the control circuit of the driving circuit, a third AND gate including a first input terminal connected to an output terminal of the second AND gate and a second input terminal connected to the control circuit of the driving circuit, a counter circuit including a first input terminal connected to an output terminal of the first OR gate and a second input terminal connected to an output terminal of the second OR gate, and a first OR gate including a first input terminal connected to an output terminal of the first AND gate, a second input terminal connected to an output terminal of the third AND gate, and a third input terminal connected to the delay circuit connected to an output terminal of the counter circuit.

The first reference voltage terminal may provide a first reference voltage obtained by summating a voltage of the input terminal of the output circuit and a first voltage which is lower than a forward voltage value of the first body diode, and the second reference voltage terminal may provide a second reference voltage which is lower than a forward voltage value of the second body diode.

In another aspect of the present disclosure, a power supply includes an output circuit including a first switch and a second switch configured to charge or discharge power input through an input terminal thereof to output through an output terminal thereof and an output controller including a driving circuit configured to control charging or discharging of the output circuit, wherein the driving circuit senses an LX node voltage of the output circuit to determine whether at least one of a first body diode included in the first switch and a second body diode included in the second switch is turned on or not, and based thereon, controls a dead time corresponding to one of the first switch and the second switch.

The driving circuit may include a dead time controller configured to control the dead time corresponding to one of the first switch and the second switch, based on the LX node voltage sensed from the output circuit, a reference voltage, and a switch control reference signal output from a control circuit of the driving circuit.

The dead time controller may include a first body diode sensing circuit configured to output a first sensing result value corresponding to a turn-on time of the first body diode, a second body diode sensing circuit configured to output a second sensing result value corresponding to a turn-on time of the second body diode, a first AND gate configured to output a first AND operation value, based on a signal for determining the turn-on/off of the first body diode and a second switch control reference signal output from the control circuit of the driving circuit, a second AND gate configured to output a second AND operation value, based on a signal for determining the turn-on/off of the second body diode and a first switch control reference signal output from the control circuit of the driving circuit, a third AND gate configured to output a third AND operation value, based on a signal for determining the turn-on/off of the second body diode and the second switch control reference signal output from the control circuit of the driving circuit, a first OR gate configured to output a first OR operation value, based on the first AND operation value output from the first AND gate and the third AND operation value output from the third AND gate, a counter circuit configured to output a counter result value for determining whether there is a time corresponding to a zero current, based on a signal for controlling the first switch and the second switch, a delay circuit configured to delay, for a certain time, the counter result value output from the counter circuit to output a delayed counter result value, and a second OR gate configured to output a second OR operation value, based on the second AND operation value output from the second AND gate and a delay value output from the delay circuit connected to an output terminal of the counter circuit.

The dead time controller may include a first body diode sensing circuit configured to output a first sensing result value corresponding to a turn-on time of the first body diode, a second body diode sensing circuit configured to output a second sensing result value corresponding to a turn-on time of the second body diode, a first AND gate configured to output a first AND operation value, based on a signal for determining the turn-on/off of the first body diode and a second switch control reference signal output from the control circuit of the driving circuit, a second AND gate configured to output a second AND operation value, based on a signal for determining the turn-on/off of the second body diode and a first switch control reference signal output from the control circuit of the driving circuit, a third AND gate configured to output a third AND operation value, based on a signal for determining the turn-on/off of the second body diode and the second switch control reference signal output from the control circuit of the driving circuit, a counter circuit configured to output a counter result value for determining whether there is a time corresponding to a zero current, based on a signal for controlling the first switch and the second switch, a delay circuit configured to delay, for a certain time, the counter result value output from the counter circuit to output a delayed counter result value, and a first OR gate configured to output a first OR operation value, based on the first AND operation value output from the first AND gate, the third AND operation value output from the third AND gate, and a delay value output from the delay circuit connected to an output terminal of the counter circuit.

### BRIEF DESCRIPTION OF THE SEVERAL VIEWS OF THE DRAWINGS

The accompanying drawings, which are included to provide a further understanding of the disclosure and are incorporated in and constitute a part of this application, illustrate embodiment(s) of the disclosure and together with the description serve to explain the principle of the disclosure. In the drawings:

FIG. 1 is a block diagram schematically illustrating a light emitting display apparatus, FIGS. 2 and 3 are diagrams for describing a configuration of a scan driver of a gate in panel (GIP) type, and FIG. 4 is an exemplary diagram of a subpixel;

FIG. 5 is a block diagram for describing a configuration associated with a power generating operation of a power supply according to a first embodiment, and FIG. 6 is a block diagram schematically illustrating some elements included in the power supply according to the first embodiment;

FIGS. 7 and 8 are diagrams for describing a charging/discharging operation of the power supply according to the first embodiment, FIGS. 9 and 10 are diagrams for describing a driving mode-based operation based on a load of the power supply according to the first embodiment, and FIGS. 11 and 12 are diagrams for describing a control method of the power supply according to the first embodiment;

FIG. 13 is a block diagram illustrating in more detail some elements included in a power supply according to a second embodiment, and FIG. 14 is a circuit configuration diagram illustrating in more detail a dead time controller illustrated in FIG. 13 according to the second embodiment;

FIGS. 15 and 16 are diagrams illustrating an operation of a circuit, switch control signals, and an Lx voltage when the power supply according to the second embodiment operates in a continuous conduction mode (CCM), FIGS. 17 and 18 are diagrams illustrating an operation of a circuit, switch control signals, and an Lx voltage when the power supply according to the second embodiment operates in a forced continuous conduction mode (FCCM), and FIG. 19 is a diagram for describing a case where the power supply according to the second embodiment performs an operation corresponding to a zero current;

FIG. 20 is a waveform diagram for describing some of elements associated with an operation of a power supply according to a third embodiment, and FIG. 21 is a circuit configuration diagram illustrating in more detail a dead time controller illustrated in FIG. 20 according to the third embodiment; and

FIGS. 22 and 23 are diagrams illustrating an operation of a circuit, switch control signals, and an Lx voltage when the power supply according to the third embodiment operates in the CCM, FIGS. 24 and 25 are diagrams illustrating an operation of a circuit, switch control signals, and an Lx voltage when the power supply according to the second embodiment operates in the FCCM, FIG. 26 is a diagram for describing a case where the power supply according to the third embodiment performs an operation corresponding to a zero current, and FIG. 27 is a waveform diagram illustrating an adaptive dead time implemented in the power supply according to the third embodiment.

### DETAILED DESCRIPTION

Hereinafter, the present disclosure will be described more fully with reference to the accompanying drawings, in which exemplary embodiments of the disclosure are shown. The disclosure may, however, be embodied in many different forms and should not be construed as being limited to the embodiments set forth herein; rather, these embodiments are provided so that this disclosure will be thorough and complete, and will fully convey the concept of the disclosure to those skilled in the art.

A display apparatus according to the present disclosure may be applied to televisions (TVs), video players, personal computers (PCs), home theaters, electronic devices for vehicles, and smartphones, but is not limited thereto. The display apparatus according to the present disclosure may be implemented as a light emitting display apparatus, a quantum dot display (QDD) apparatus, or a liquid crystal display (LCD) apparatus. Hereinafter, for convenience of description, a light emitting display apparatus self-emitting light by using an inorganic light emitting diode or an organic light emitting diode will be described for example.

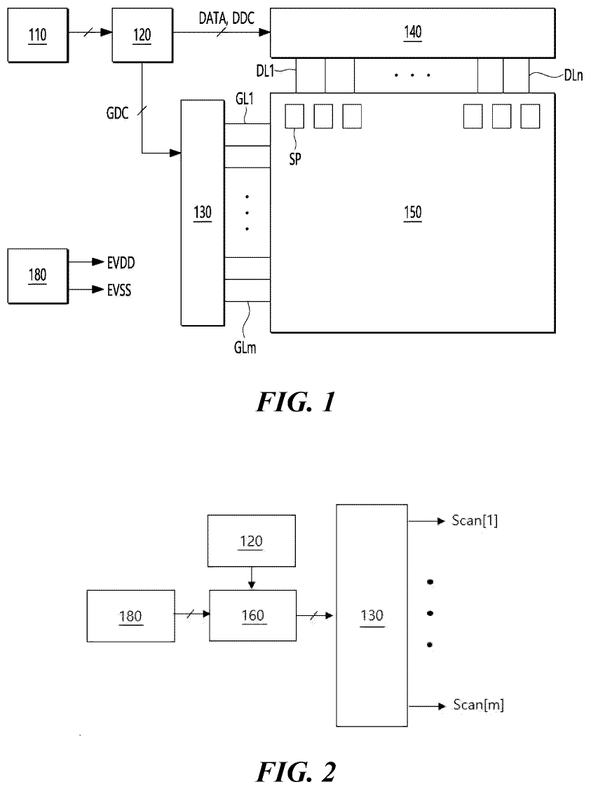

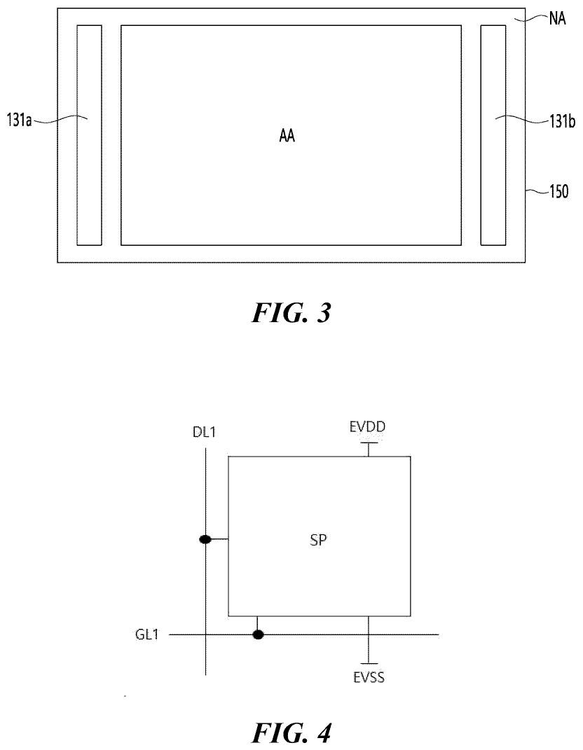

FIG. 1 is a block diagram schematically illustrating a light emitting display apparatus, FIGS. 2 and 3 are diagrams for describing a configuration of a scan driver of a gate in panel (GIP) type, and FIG. 4 is an exemplary diagram of a subpixel.

As illustrated in FIGS. 1 to 4, a light emitting display apparatus according to an embodiment of the present disclosure may include a timing controller 120, a scan driver 130, a data driver 140, a display panel 150, and a power supply 180. The scan driver 130 and the data driver 140 can be defined as panel driver.

The video supply unit 110 (a set or a host system) may output a video data signal supplied from the outside or various driving signals and an image data signal stored in an internal memory thereof. The video supply unit 110 may supply a data signal and the various driving signals to the timing controller 120.

The timing controller 120 may output a gate timing control signal GDC for controlling an operation timing of the scan driver 130, a data timing control signal DDC for controlling an operation timing of the data driver 140, and various synchronization signals (a vertical synchronization signal Vsync and a horizontal synchronization signal Hsync). The timing controller 120 may provide the data driver 140 with the data timing control signal DDC and a data signal DATA supplied from the video supply unit 110. The timing controller 120 may be implemented as an integrated circuit (IC) type and may be mounted on a printed circuit board (PCB), but is not limited thereto.

The scan driver 130 may output a scan signal (or a scan voltage) in response to the gate timing control signal GDC supplied from the timing controller 120. The scan driver 130 may supply the scan signal to a plurality of subpixels, included in the display panel 150, through a plurality of gate lines GL1 to GLm. The scan driver 130 may be implemented as an IC type or may be directly provided on the display panel 150 in a GIP type, but is not limited thereto. Hereinafter, however, for convenience of description, a GIP-type scan driver as in FIGS. 2 and 3 will be described for example.

As illustrated in FIGS. 2 and 3, a GIP-type scan driver 130 may include shift registers 130a and 130b which are formed as a GIP type at one side and the other side of a non-display area NA of the display panel 150. The shift registers 130a and 130b may be formed as a thin film type in the non-display area NA of the display panel 150, based on the GIP type. The GIP-type scan driver 130 may output scan signals Scan [1] to Scan [m] for turning on or off transistors provided in a display area AA of the display panel 150.

The GIP-type scan driver 130 may operate based on voltages and signals output from the timing controller 120, the power supply 180, and the level shifter 160. The level shifter 160 may generate signals needed for driving of the GIP-type scan driver 130 (130a and 130b), based on voltages and signals output from the timing controller 120 and the power supply 180.

In response to the data timing control signal DDC supplied from the timing controller 120, the data driver 140 may sample and latch the data signal DATA, convert a digital data signal into an analog data voltage, based on a gamma reference voltage, and output the analog data voltage. The data driver 140 may respectively supply data voltages to the subpixels of the display panel 150 through a plurality of data lines DL1 to DLn. The data driver 140 may be implemented as an IC type or may be mounted on the display panel 150 or a PCB, but is not limited thereto.

The power supply 180 may generate an output voltage including a high-level voltage and a low-level voltage, based on an input voltage supplied from the outside, and may output the high-level voltage and the low-level voltage through a high-level voltage line EVDD and a low-level voltage line EVSS each connected to the display panel 150. The power supply 180 may generate and output a voltage (for example, a gate high voltage and a gate low voltage) needed for driving of the scan driver 130 or a voltage (for example, a drain voltage and a half drain voltage) needed for driving of the data driver 140, in addition to the high-level voltage and the low-level voltage.

The display panel 150 may be manufactured based on a substrate, having stiffness or flexibility, such as glass, silicon, or polyimide. The display panel 150 may include a plurality of subpixels SP for displaying an image, based on the high-level voltage, the low-level voltage, and a driving signal including the scan signal and a data voltage. As illustrated in FIG. 4, the subpixel SP may be connected to a first data line DL1, a first gate line GL1, a high-level voltage line EVDD, and a low-level voltage line EVSS. The subpixel SP may self-emit light. The subpixel SP may emit light having one color of red, green, blue, and white.

Hereinabove, each of the timing controller 120, the scan driver 130, and the data driver 140 has been described as an individual element. However, based on an implementation type of the light emitting display apparatus, one or more of the timing controller 120, the scan driver 130, and the data driver 140 may be integrated into one IC.

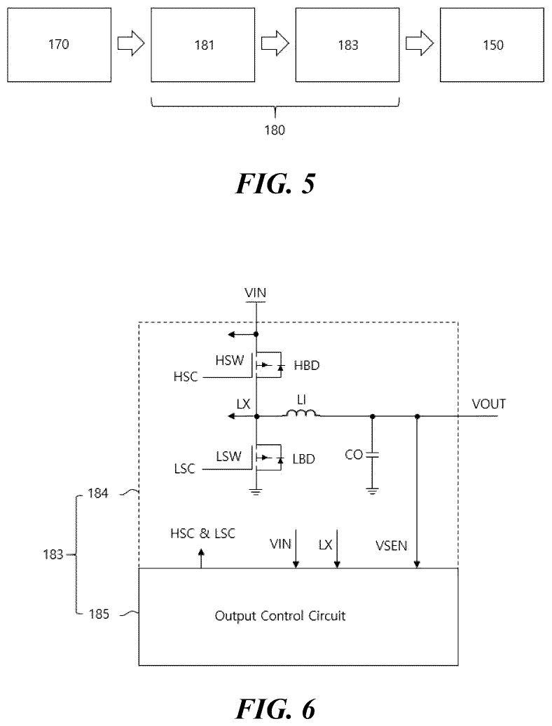

FIG. 5 is a block diagram for describing a configuration associated with a power generating operation of a power supply 180 according to a first embodiment, and FIG. 6 is a block diagram schematically illustrating some elements included in the power supply 180 according to the first embodiment.

As illustrated in FIG. 5, the power supply 180 may include a first power supply circuit 181 and a second power supply circuit 183 so as to generate an output power which is to be supplied to a display panel 150, based on an external power source 170. For example, the external power source 170 may be selected as a battery of 12 V, but is not limited thereto.

The first power supply circuit 181 may be selected as a pre-boost circuit which boosts an input power supplied from the external power source 170 to generate an output power. The second power supply circuit 183 may be selected as a buck converter circuit which generates an output power for driving the display panel 150, based on the output power generated by the first power supply circuit 181. For example, the first power supply circuit 181 may boost 12 V to output 15 V, and the second power supply circuit 183 may decrease 15 V to output 12.5 V, but the present embodiment is not limited thereto. That is, the power supply 180 may include a DC-DC converter which converts a first direct current (DC) voltage into a second DC voltage to output the second DC voltage.

Furthermore, in the present disclosure, the first power supply circuit 181 and the second power supply circuit 183 may be individually described as separate elements, but this may be merely an embodiment for providing convenience of description and helping understanding. Also, the first power supply circuit 181 may be omitted based on an external power source or device. Therefore, in the following description, for convenience of description, the second power supply circuit 183 may be described as a power supply.

As illustrated in FIG. 6, a power supply 183 may include an output circuit 184 and an output controller 185, so as to decrease power input through an input terminal VIN.

The output circuit 184 may charge or discharge power input through the input terminal VIN and may provide power which is to be output through an output terminal VOUT. The output controller 185 may be charged or discharged with power input through the input terminal VIN and may control the output circuit 184 to efficiently generate a desired power.

The output circuit 184 may include a first switch HSW, a second switch LSW, an inductor LI, and an output capacitor CO. The first switch HSW may include a first body diode HBD, and the second switch LSW may include a second body diode LBD.

The first switch HSW may include a first electrode connected to the input terminal VIN, a second electrode connected to an LX node LX connected to a first electrode of the second switch LSW and a first electrode of the inductor LI, and a gate electrode connected to a first switch control line HSC. The second switch LSW may include a first electrode connected to the LX node LX connected to the second electrode of the first switch HSW and the first electrode of the inductor LI, a second electrode connected to a ground terminal, and a gate electrode connected to a second switch control line LSC. The inductor LI may include the first electrode connected to the first electrode of the second switch LSW and the second electrode of the first switch HSW and a second electrode connected to the output terminal VOU. The output capacitor CO may include a first electrode connected to the output terminal VOU and a second electrode connected to the ground terminal.

The output controller 185 may control an on/off switching timing of each of the first switch HSW and the second switch LSW, based on a current and a voltage formed at the input terminal VIN, the LX node LX, and the output terminal VOUT of the output circuit 184. The output controller 185 may generate a first switch control signal and a second switch control signal for controlling the on/off switching timing of each of the first switch HSW and the second switch LSW. The first switch control signal and the second switch control signal output from the output controller 185 may be output through the first switch control line HSC and the second switch control line LSC.

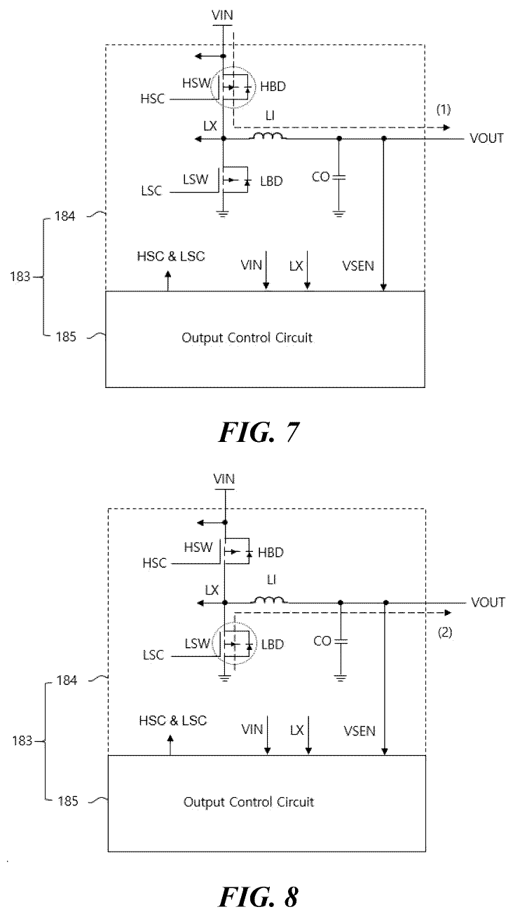

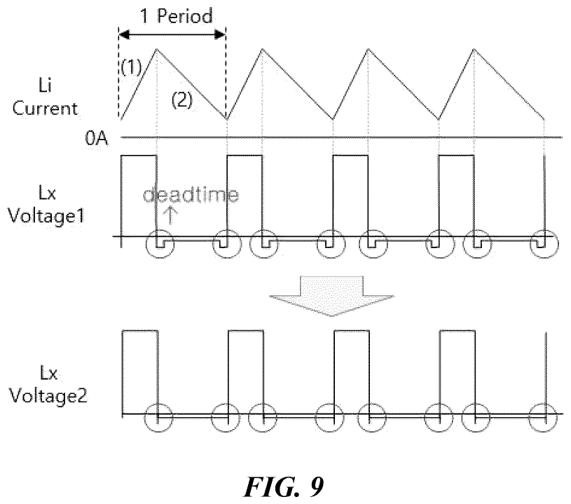

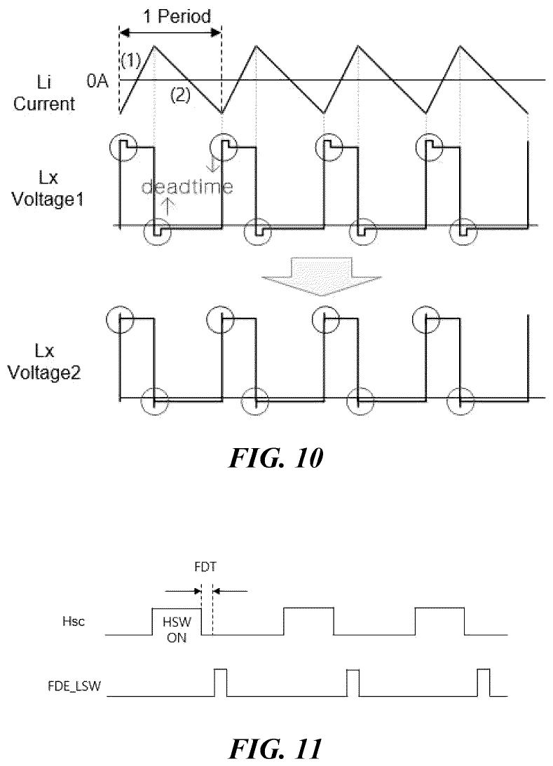

FIGS. 7 and 8 are diagrams for describing a charging/discharging operation of the power supply 183 according to the first embodiment, FIGS. 9 and 10 are diagrams for describing a driving mode-based operation based on a load of the power supply 183 according to the first embodiment, and FIGS. 11 and 12 are diagrams for describing a control method of the power supply 183 according to the first embodiment.

As illustrated in FIGS. 6 to 8, when the first switch HSW is turned on in response to the first switch control signal output from the output controller 185, the power supply 183 may perform a charging operation along a path (1). When the second switch LSW is turned on in response to the second switch control signal output from the output controller 185, the power supply 183 may perform a discharging operation along a path (2). The power supply 183 may output a current and a voltage through the charging operation and the discharging operation.

As illustrated in FIGS. 6, 9, and 10, the power supply 183 may operate in a continuous conduction mode (CCM) or may operate in a forced continuous conduction mode (FCCM), based on a load of an output terminal. For example, the CCM of FIG. 9 may be selected when a load current of the output terminal is high (when the amount of load current is high), and the FCCM of FIG. 10 may be selected when the load current of the output terminal is low (when the amount of load current is low).

The CCM may be defined as a mode where an inductor current (an Li current or an output current) always has a positive (+) value and operates with including no 0 value, and the FCCM may be defined as a mode where an inductor current (an Li current) has a positive (+) value or a negative (−) value and operates with including a 0 value.

Referring to an inductor voltage (Lx voltage 1), it may be seen that the power supply before an embodiment is applied has a relatively long dead time when performing a switching operation of generating power. A dead time may be a time which is set so that a switching operation is not performed for preventing shoot-through between the first switch HSW and the second switch LSW included in the output circuit 184.

When a dead time is very short, a shoot-through problem caused by overlapping of an operation time of the first switch HSW and an operation time of the second switch LSW may occur. On the other hand, when a dead time is long, switch conduction loss caused by a non-operation time of the first switch HSW and a non-operation time of the second switch LSW may increase.

Referring to an inductor voltage (Lx voltage 2), it may be seen that the power supply 183 after an embodiment is applied has a relatively short dead time when performing a switching operation of generating power. A dead time may be designed (set) so that an on/off switching operation of each of the first switch HSW and the second switch LSW is fixed, and thus, may be provided as a fixed dead time.

However, as seen in FIGS. 6, 11, and 12, the power supply 183 according to the first embodiment may control an on time (ON) of one of the first switch HSW and the second switch LSW, based on the inductor voltage (Lx voltage 2), and may thus reduce a fixed dead time (FDT).

To this end, the output controller 185 may sense an LX node (LX) voltage of the output circuit 184 to determine whether at least one of the first body diode HBD included in the first switch HSW and the second body diode LBD included in the second switch HSW is turned on or not. Also, based thereon, the output controller 185 may turn on one of the first switch HSW and the second switch LSW to control (artificially end) a dead time, in order to reduce conduction loss caused by a body diode. Hereinafter, a CCM operation condition and an FCCM operation condition will be described below with being differentiated from each other.

### CCM Operation Condition

In a case where the power supply 183 operates in the CCM, the output controller 185 may sense the LX node (LX) voltage of the output circuit 184 to check the turn-on of the second body diode LBD included in the second switch LSW and may then turn on the first switch HSW or the second switch LSW to control (artificially end) a dead time caused by the first switch HSW or the second switch LSW.

### FCCM Operation Condition

In a case where the power supply 183 operates in the FCCM, the output controller 185 may sense the LX node (LX) voltage of the output circuit 184 to check the turn-on of the first body diode HBD included in the first switch HSW and may then turn on the first switch HSW to artificially end a dead time caused by the first switch HSW. Also, the output controller 185 may sense the LX node (LX) voltage of the output circuit 184 to check the turn-on of the second body diode LBD included in the second switch LSW and may then turn on the second switch LSW to artificially end a dead time caused by the second switch LSW.

Furthermore, when the first switch HSW is turned off at a time corresponding to a zero current, the second body diode LBD included in the second switch LSW may not be turned on. Accordingly, after the fixed dead time, the output controller 185 may artificially turn on the second switch LSW to maintain the FCCM operation condition.

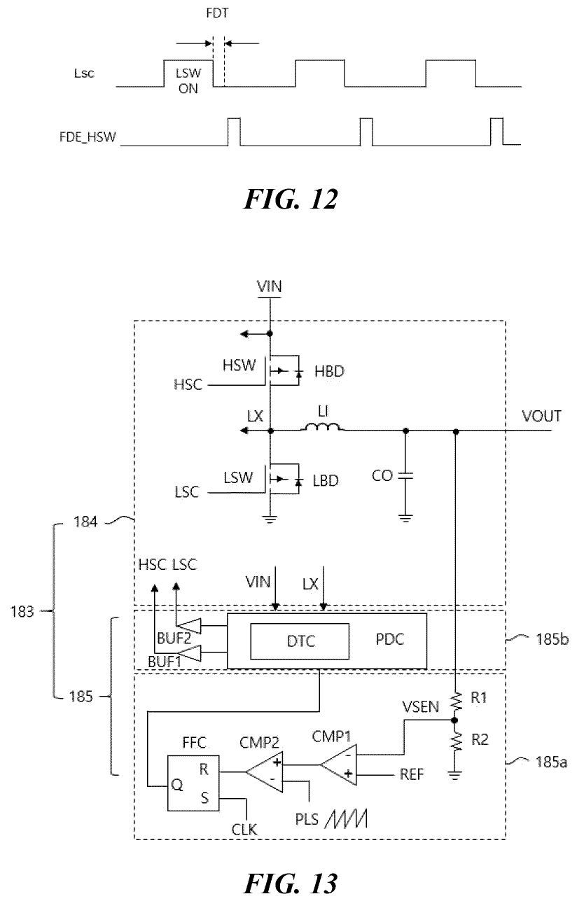

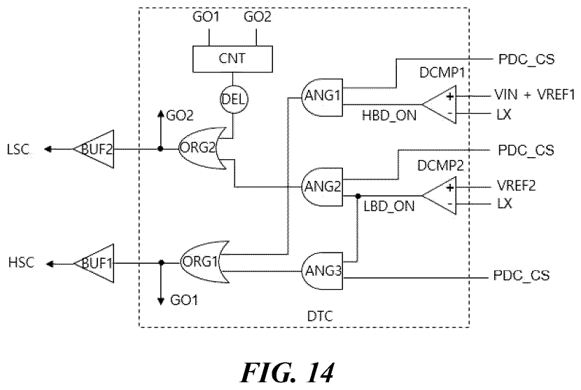

FIG. 13 is a block diagram illustrating in more detail some elements included in a power supply 183 according to a second embodiment, and FIG. 14 is a circuit configuration diagram illustrating in more detail a dead time controller illustrated in FIG. 13 according to the second embodiment.

As illustrated in FIG. 13, the power supply 183 may include an output circuit 184 and an output controller 185, so as to decrease power input through an input terminal VIN to output through an output terminal VOUT.

The output circuit 184 may charge or discharge power input through the input terminal VIN and may provide power which is to be output through an output terminal VOUT. The output controller 185 may be charged or discharged with power input through the input terminal VIN and may control the output circuit 184 to efficiently generate a desired power.

The output circuit 184 may include a first switch HSW, a second switch LSW, an inductor LI, and an output capacitor CO. The first switch HSW may include a first body diode HBD, and the second switch LSW may include a second body diode LBD. A connection relationship between the elements included in the output circuit 184 has been described in the first embodiment, and thus, the above descriptions of the first embodiment may be applied thereto.

The output controller 185 may control an on/off switching timing of each of the first switch HSW and the second switch LSW, based on a current and a voltage formed at the input terminal VIN, an LX node LX, and the output terminal VOUT of the output circuit 184. The output controller 185 may generate a first switch control signal and a second switch control signal for controlling the on/off switching timing of each of the first switch HSW and the second switch LSW. The first switch control signal and the second switch control signal output from the output controller 185 may be output through the first switch control line HSC and the second switch control line LSC. The output controller 185 may include a first output control circuit 185a and a second output control circuit 185b.

The first output control circuit 185a may control or vary an operation condition of the second output control circuit 185b, based on a current and a voltage formed at the output terminal VOUT of the output circuit 184. To this end, the first output control circuit 185a may include a first resistor R1, a second resistor R2, a first comparator CMP1, a second comparator CMP2, and a flip-flop FFC.

The first resistor R1 and the second resistor R2 may be serially connected between the output terminal VOUT of the output circuit 184 and a ground terminal, so as to sense a voltage output through the output terminal VOUT of the output circuit 184.

The first comparator CMP1 may compare a sensing value VSEN, obtained through an inverting terminal (−) thereof connected to a node between the first resistor R1 and the second resistor R2, with an internal voltage obtained through a noninverting terminal (+) thereof connected to an internal voltage terminal REF to generate a first comparison result value.

The second comparator CMP2 may compare a pulse value PLS, obtained through an inverting terminal (−) thereof, with the first comparison result value of the first comparator CMP1 obtained through a noninverting terminal (+) thereof to generate a second comparison result value. The pulse value PLS may be generated and applied as a sawtooth-wave signal by a pulse generator.

The flip-flop FFC may generate a controller control signal which is to be supplied to the second output control circuit 185b, based on the second comparison result value of the second comparator CMP2 obtained through a first terminal R thereof and a clock signal value CLK obtained through a second terminal S thereof. The flip-flop FFC may be selected as an RS flip-flop and may output a controller control signal as a type corresponding to a true value, based on an input value of 0 or 1 applied to the first terminal R and the second terminal S thereof. For example, the flip-flop FFC may output a controller control signal as a square wave, based on the input value of 0 or 1 applied to the first terminal R and the second terminal S thereof. The pulse value PLS and the clock signal value CLK may be generated with the same frequency, but a width of the pulse value PLS may be greater than that of the clock signal value CLK. Also, the pulse value PLS may be used when operating in a voltage mode instead of a current mode.

The second output control circuit 185b may generate the first switch control signal and the second switch control signal for controlling the on/off switching timing of each of the first switch HSW and the second switch LSW, based on a signal output from the first output control circuit 185a. The second output control circuit 185b may artificially end a dead time of each of the first switch HSW and the second switch LSW, based on a current and a voltage formed at the input terminal VIN and the LX node LX of the output circuit 184.

To this end, the second output control circuit 185b may include a driving circuit PDC including a dead time controller DTC, a first buffer BUF1, and a second buffer BUF2. The first buffer BUF1 and the second buffer BUF2 may configure the first switch control signal and the second switch control signal, output from the driving circuit PDC, as a voltage type to apply to the first switch HSW and the second switch LSW. The driving circuit PDC may generate a switch control reference signal for providing the first switch control signal and the second switch control signal, based on the controller control signal output from the flip-flop FFC.

As illustrated in FIGS. 13 and 14, the dead time controller DTC may include a first body diode sensing circuit DCMP1, a second body diode sensing circuit DCMP2, a first AND gate ANG1, a second AND gate ANG2, a third AND gate ANG3, a first OR gate ORG1, a second OR gate ORG2, a counter circuit CNT, and a delay circuit DEL.

The first body diode sensing circuit DCMP1 may include a noninverting terminal (+), connected to a first reference voltage terminal (VIN+VREF1) which provides a first reference voltage obtained by summating a first voltage and a voltage of the input terminal VIN of the output circuit 184, and an inverting terminal (−) connected to the LX node LX of the output circuit 184. The first body diode sensing circuit DCMP1 may output a first sensing result value HBD_ON corresponding to a turn-on time of the first body diode HBD, based on the voltage of the input terminal VIN of the output circuit 184 and a voltage of the LX node LX of the output circuit 184. Here, the first voltage may be set to a voltage value (for example, 0.6 V) which is lower than a forward voltage value Vf of the first body diode HBD.

The second body diode sensing circuit DCMP2 may include a noninverting terminal (+), connected to a second reference voltage terminal VREF2 which provides a second voltage having a level which differs from that of the first voltage, and an inverting terminal (−) connected to the LX node LX of the output circuit 184. The second body diode sensing circuit DCMP2 may output a second sensing result value LBD_ON corresponding to a turn-on time of the second body diode LBD, based on the voltage of the input terminal VIN of the output circuit 184 and the voltage of the LX node LX of the output circuit 184. Here, the second voltage may be set to a voltage value (for example, −0.6 V) which is lower than a forward voltage value Vf of the second body diode LBD.

The first AND gate ANG1 may include a first input terminal connected to an output terminal of the first body diode sensing circuit DCMP1 and a second input terminal connected to a control circuit PDC_CS of the driving circuit PDC. The first AND gate ANG1 may output a first AND operation value of 0 or 1, based on a signal for determining the turn-on/off of the first body diode HBD and a second switch control reference signal output from the control circuit PDC_CS of the driving circuit PDC.

The second AND gate ANG2 may include a first input terminal connected to an output terminal of the second body diode sensing circuit DCMP2 and a second input terminal connected to the control circuit PDC_CS of the driving circuit PDC. The second AND gate ANG2 may output a second AND operation value of 0 or 1, based on a signal for determining the turn-on/off of the second body diode LBD and a first switch control reference signal output from the control circuit PDC_CS of the driving circuit PDC.

The third AND gate ANG3 may include a first input terminal connected to an output terminal of the second AND gate ANG2 and a second input terminal connected to the control circuit PDC_CS of the driving circuit PDC. The third AND gate ANG3 may output a third AND operation value of 0 or 1, based on a signal for determining the turn-on/off of the second body diode LBD and the second switch control reference signal output from the control circuit PDC_CS of the driving circuit PDC.

The first OR gate ORG1 may include a first input terminal connected to an output terminal of the first AND gate ANG1 and a second input terminal connected to an output terminal of the third AND gate ANG3. The first OR gate ORG1 may output a first OR operation value of 0 or 1, based on a first AND operation value output from the first AND gate ANG1 and a third AND operation value output from the third AND gate ANG3. The first OR operation value output from the first OR gate ORG1 may be applied to the first buffer BUF1 and may be output as a first switch control signal HSC for controlling the first switch HSW.

The second OR gate ORG2 may include a first input terminal connected to an output terminal of the second AND gate ANG2 and a second input terminal connected to the delay circuit DEL connected to an output terminal of the counter circuit CNT. The second OR gate ORG2 may output a second OR operation value of 0 or 1, based on a second AND operation value output from the second AND gate ANG2 and a delay value output from the delay circuit DEL connected to the output terminal of the counter circuit CNT. The second OR operation value output from the second OR gate ORG2 may be applied to the second buffer BUF2 and may be output as a second switch control signal LSC for controlling the second switch HSW.

The counter circuit CNT may include a first input terminal connected to an output terminal of the first OR gate ORG1 and a second input terminal connected to an output terminal of the second OR gate ORG2. The counter circuit CNT may output a counter result value for determining whether there is a time corresponding to a zero current, based on a falling time of each of the first switch control signal and the second switch control signal. The delay circuit DEL may delay, for a certain time, the counter result value output from the counter circuit CNT to output a delayed counter result value. The counter result value output from the counter circuit CNT may be used as a dead time end signal.

In the above description, an example where each of the first body diode sensing circuit DCMP1 and the second body diode sensing circuit DCMP2 is configured with a comparator is illustrated, but the present embodiment is not limited thereto. Also, in the above description, an example where the delay circuit DEL delays the counter result value for a certain time to output is illustrated, but the present embodiment is not limited thereto.

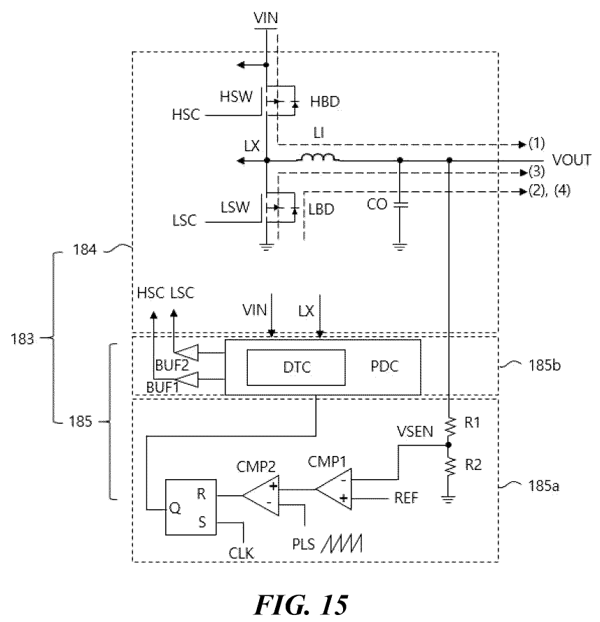

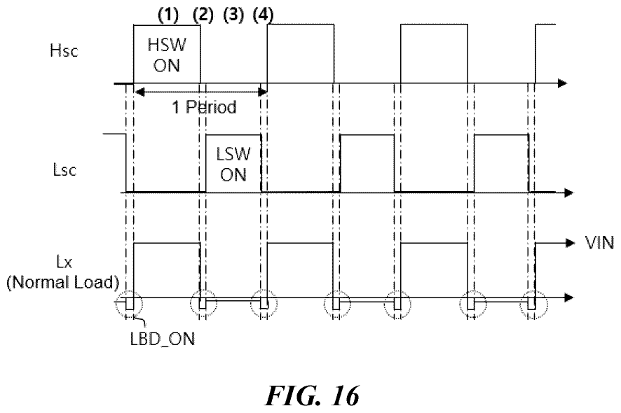

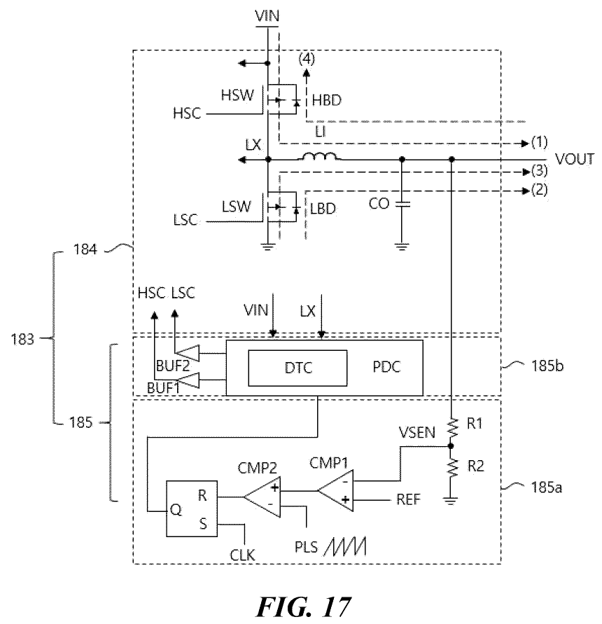

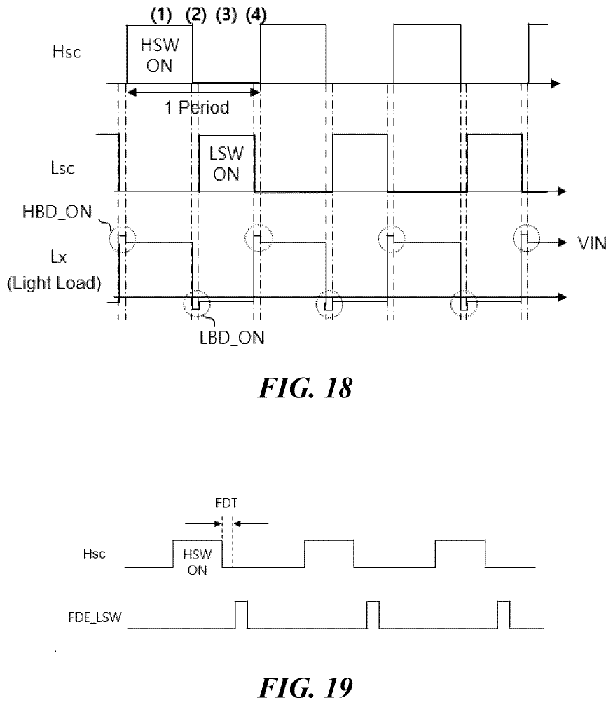

FIGS. 15 and 16 are diagrams illustrating an operation of a circuit, switch control signals, and an Lx voltage when the power supply 183 according to the second embodiment operates in the CCM, FIGS. 17 and 18 are diagrams illustrating an operation of a circuit, switch control signals, and an Lx voltage when the power supply 183 according to the second embodiment operates in the FCCM, and FIG. 19 is a diagram for describing a case where the power supply 183 according to the second embodiment performs an operation corresponding to a zero current.

As illustrated in FIGS. 15 to 18, the power supply 183 according to the second embodiment may alternately turn on or off the first switch HSW and the second switch LSW to generate an output power, in response to a first switch control signal Hsc and a second switch control signal Lsc.

One period in a process of generating the output power may include a first period 1 where the first switch HSW is turned on and the second switch LSW is turned off, a second period 2 where the first switch HSW and the second switch LSW are turned off, a third period 3 where the first switch HSW is turned off and the second switch LSW is turned on, and a fourth period 4 where the first switch HSW and the second switch LSW are turned off.

In a case where the power supply 183 according to the second embodiment operates in the CCM or operates in the FCCM, an Lx voltage Lx may be generated to be equal/similar to a level corresponding to power input through the input terminal VIN of the output circuit 184.

In a case where the power supply 183 operates in the CCM, a dead time based on the turn-on LBD_ON of the second body diode LBD may be in the second period 2 and the fourth period 4. Also, in a case where the power supply 183 operates in the FCCM, a dead time based on the turn-on HBD_ON or LBD_ON of the first body diode HBD or the second body diode LBD may be in the second period 2 and the fourth period 4.

As illustrated in FIGS. 13 to 18, according to the second embodiment, based on the elements described above, the dead time controller DTC may sense an LX node (LX) voltage of the output circuit 184 to check the turn-on of the first body diode HBD included in the first switch HSW and may then turn on the first switch HSW to artificially end a dead time based on the first switch HSW. Also, based on the elements described above, the dead time controller DTC may sense the LX node (LX) voltage of the output circuit 184 to check the turn-on of the second body diode LBD included in the second switch LSW and may then turn on the second switch LSW to artificially end a dead time based on the second switch LSW. Accordingly, the power supply 183 according to the second embodiment may reduce a dead time to stably and efficiently generate power.

As illustrated in FIGS. 15 to 19, according to the second embodiment, based on the elements described above, when the first switch HSW is turned off at a time corresponding to a zero current, the dead time controller DTC may artificially turn on the second switch LSW, based on a dead time end signal FDE_LSW which is generated after being delayed for a certain time at a fixed dead time FDT. Accordingly, the power supply 183 according to the second embodiment may perform a normal switching operation despite a zero current condition where a current does not flow, based on the control of a dead time.

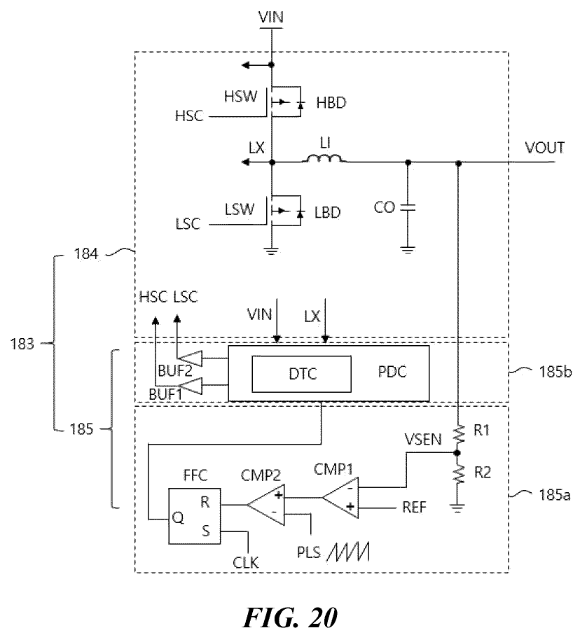

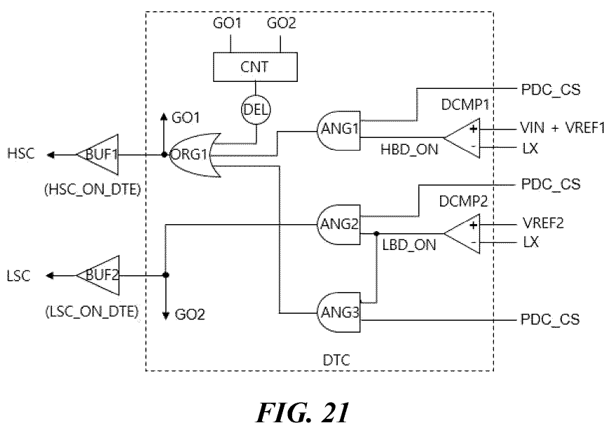

FIG. 20 is a waveform diagram for describing some of elements associated with an operation of a power supply 183 according to a third embodiment, and FIG. 21 is a circuit configuration diagram illustrating in more detail a dead time controller illustrated in FIG. 20 according to the third embodiment.

As illustrated in FIG. 20, the power supply 183 may include an output circuit 184 and an output controller 185, so as to decrease power input through an input terminal VIN to output through an output terminal VOUT. The power supply 183 according to the third embodiment may have a difference in configuration of the dead time controller DTC compared to the second embodiment, and thus, a difference therebetween will be described below.

As illustrated in FIGS. 20 and 21, the dead time controller DTC may include a first body diode sensing circuit DCMP1, a second body diode sensing circuit DCMP2, a first AND gate ANG1, a second AND gate ANG2, a third AND gate ANG3, a first OR gate ORG1, a second OR gate ORG2, a counter circuit CNT, and a delay circuit DEL.

The first body diode sensing circuit DCMP1 may include a noninverting terminal (+), connected to a first reference voltage terminal (VIN+VREF1) which provides a first reference voltage obtained by summating a voltage of the input terminal VIN of the output circuit 184 and a voltage of a first voltage terminal VREF1, and an inverting terminal (−) connected to the LX node LX of the output circuit 184. The first body diode sensing circuit DCMP1 may output a first sensing result value HBD_ON corresponding to a turn-on time of the first body diode HBD, based on the voltage of the input terminal VIN of the output circuit 184 and a voltage of the LX node LX of the output circuit 184. Here, the first voltage may be set to a voltage value (for example, 0.6 V) which is lower than a forward voltage value Vf of the first body diode HBD.

The second body diode sensing circuit DCMP2 may include a noninverting terminal (+), connected to a second reference voltage terminal VREF2 which provides a second voltage having a level which differs from that of the first voltage, and an inverting terminal (−) connected to the LX node LX of the output circuit 184. The second body diode sensing circuit DCMP2 may output a second sensing result value LBD_ON corresponding to a turn-on time of the second body diode LBD, based on the voltage of the input terminal VIN of the output circuit 184 and the voltage of the LX node LX of the output circuit 184. Here, the second voltage may be set to a voltage value (for example, −0.6 V) which is lower than a forward voltage value Vf of the second body diode LBD.

The first AND gate ANG1 may include a first input terminal connected to an output terminal of the first body diode sensing circuit DCMP1 and a second input terminal connected to a control circuit PDC_CS of the driving circuit PDC. The first AND gate ANG1 may output a first AND operation value of 0 or 1, based on a signal for determining the turn-on/off of the first body diode HBD and a second switch control reference signal output from the control circuit PDC_CS of the driving circuit PDC.

The second AND gate ANG2 may include a first input terminal connected to an output terminal of the second body diode sensing circuit DCMP2 and a second input terminal connected to the control circuit PDC_CS of the driving circuit PDC. The second AND gate ANG2 may output a second AND operation value of 0 or 1, based on a signal for determining the turn-on/off of the second body diode LBD and a first switch control reference signal output from the control circuit PDC_CS of the driving circuit PDC. The second AND operation value output from the first AND gate ANG2 may be applied to the second buffer BUF2 and may be output as a second switch control signal LSC for controlling the second switch LSW.

The third AND gate ANG3 may include a first input terminal connected to an output terminal of the second AND gate ANG2 and a second input terminal connected to the control circuit PDC_CS of the driving circuit PDC. The third AND gate ANG3 may output a third AND operation value of 0 or 1, based on a signal for determining the turn-on/off of the second body diode LBD and the second switch control reference signal output from the control circuit PDC_CS of the driving circuit PDC.

The first OR gate ORG1 may include a first input terminal connected to an output terminal of the first AND gate ANG1, a second input terminal connected to an output terminal of the third AND gate ANG3, and a third input terminal connected to the delay circuit DEL connected to an output terminal of the counter circuit CNT. The first OR gate ORG1 may output a first OR operation value of 0 or 1, based on a first AND operation value output from the first AND gate ANG1, a third AND operation value output from the third AND gate ANG3, and a delay value output from the delay circuit DEL connected to the output terminal of the counter circuit CNT. The first OR operation value output from the first OR gate ORG1 may be applied to the first buffer BUF1 and may be output as a first switch control signal HSC for controlling the first switch HSW.

The counter circuit CNT may include a first input terminal connected to an output terminal of the first OR gate ORG1 and a second input terminal connected to an output terminal of the second AND gate ANG2. The counter circuit CNT may output a counter result value for determining whether there is a time corresponding to a zero current, based on a falling time of each of the first switch control signal and the second switch control signal. The delay circuit DEL may delay, for a certain time, the counter result value output from the counter circuit CNT to output a delayed counter result value. The counter result value output from the counter circuit CNT may be used as a dead time end signal.

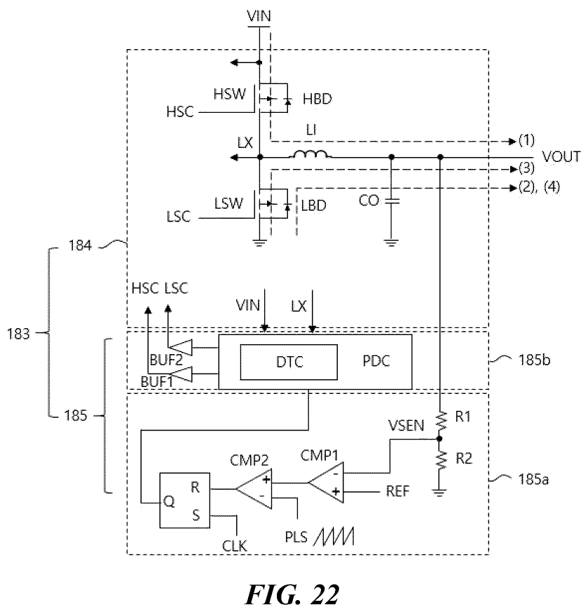

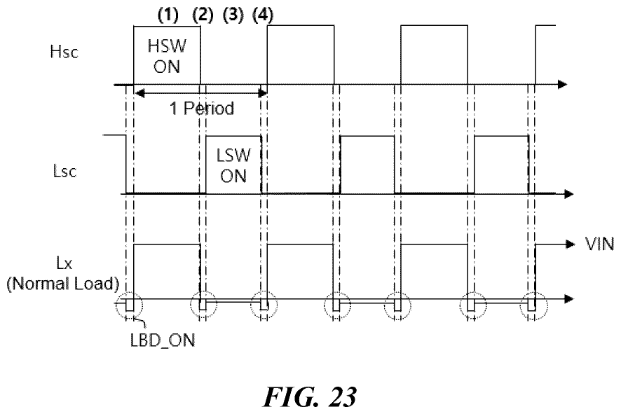

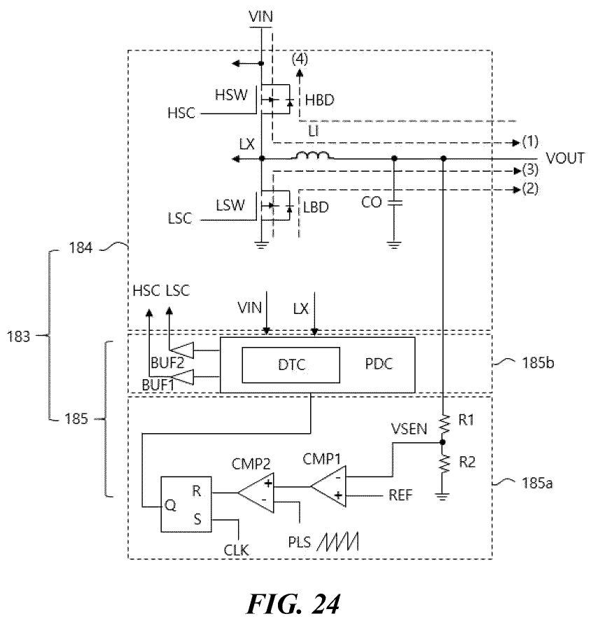

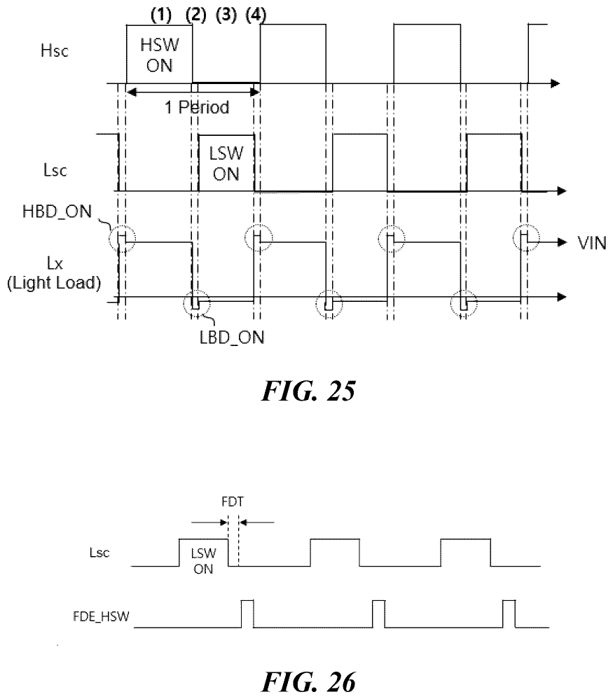

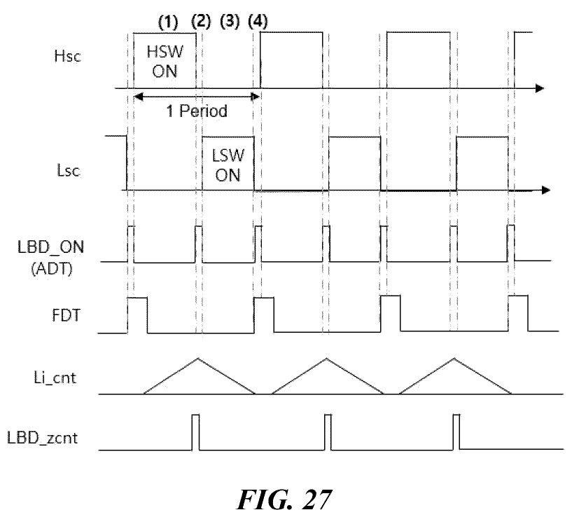

FIGS. 22 and 23 are diagrams illustrating an operation of a circuit, switch control signals, and an Lx voltage when the power supply 183 according to the third embodiment operates in the CCM, FIGS. 24 and 25 are diagrams illustrating an operation of a circuit, switch control signals, and an Lx voltage when the power supply 183 according to the second embodiment operates in the FCCM, FIG. 26 is a diagram for describing a case where the power supply 183 according to the third embodiment performs an operation corresponding to a zero current, and FIG. 27 is a waveform diagram illustrating an adaptive dead time implemented in the power supply 183 according to the third embodiment.

As illustrated in FIGS. 22 and 23, the power supply 183 according to the third embodiment may alternately turn on or off the first switch HSW and the second switch LSW to generate an output power, in response to a first switch control signal Hsc and a second switch control signal Lsc.

One period in a process of generating the output power may include a first period 1 where the first switch HSW is turned on and the second switch LSW is turned off, a second period 2 where the first switch HSW and the second switch LSW are turned off, a third period 3 where the first switch HSW is turned off and the second switch LSW is turned on, and a fourth period 4 where the first switch HSW and the second switch LSW are turned off.

In a case where the power supply 183 according to the third embodiment operates in the CCM or operates in the FCCM, an Lx voltage Lx may be generated to be equal/similar to a level corresponding to power input through the input terminal VIN of the output circuit 184.

In a case where the power supply 183 operates in the CCM, a dead time based on the turn-on LBD_ON of the second body diode LBD may be in the second period 2 and the fourth period 4. Also, in a case where the power supply 183 operates in the FCCM, a dead time based on the turn-on HBD_ON or LBD_ON of the first body diode HBD or the second body diode LBD may be in the second period 2 and the fourth period 4.

As illustrated in FIGS. 20 to 25, according to the third embodiment, based on the elements described above, the dead time controller DTC may sense an LX node (LX) voltage of the output circuit 184 to check the turn-on of the first body diode HBD included in the first switch HSW and may then turn on the first switch HSW to artificially end a dead time based on the first switch HSW. Also, based on the elements described above, the dead time controller DTC may sense the LX node (LX) voltage of the output circuit 184 to check the turn-on of the second body diode LBD included in the second switch LSW and may then turn on the second switch LSW to artificially end a dead time based on the second switch LSW. Accordingly, the power supply 183 according to the third embodiment may reduce a dead time to stably and efficiently generate power.

As illustrated in FIGS. 20 to 26, according to the third embodiment, based on the elements described above, when the second switch LSW is turned off at a time corresponding to a zero current, the dead time controller DTC may artificially turn on the first switch HSW, based on a dead time end signal FDE_LSW which is generated after being delayed for a certain time at a fixed dead time FDT. Accordingly, the power supply 183 according to the third embodiment may perform a normal switching operation despite a zero current condition where a current does not flow, based on the control of a dead time.

As illustrated in FIGS. 20, 21, and 27, the third power supply 183 according to the third embodiment may operate based on an adaptive dead time ADT provided by the dead time controller DTC despite there being the fixed dead time FDT, thereby generating power. This may be an embodiment illustrated in FIG. 27, and it may be seen that a dead time is at only a time corresponding to the turn-on LBD_ON of the second body diode LBD. Also, in FIG. 27, Li_cnt may denote an inductor current which flows through the inductor LI, and LBD_zent may denote a signal which turns on the second body diode LBD at a time corresponding to a zero current.

Hereinabove, the present disclosure may provide a power supply and a display apparatus including the same, which may improve power consumption and may reduce a dead time for which a switching operation is not performed, thereby stably and efficiently generating power. Also, the present disclosure may provide a power supply and a display apparatus including the same, which may allow a normal switching operation to be performed despite a zero current condition where a current does not flow, based on the control of a dead time, thereby maintaining the stability of driving.

The effects according to the present disclosure are not limited to the above examples, and other various effects may be included in the specification.

While the present disclosure has been particularly shown and described with reference to exemplary embodiments thereof, it will be understood by those of ordinary skill in the art that various changes in form and details may be made therein without departing from the spirit and scope of the present disclosure including the following claims.

The various embodiments described above can be combined to provide further embodiments. Aspects of the embodiments can be modified, if necessary to employ concepts of the various embodiments to provide yet further embodiments.

These and other changes can be made to the embodiments in light of the above-detailed description. In general, in the following claims, the terms used should not be construed to limit the claims to the specific embodiments disclosed in the specification and the claims, but should be construed to include all possible embodiments along with the full scope of equivalents to which such claims are entitled. Accordingly, the claims are not limited by the disclosure.

1. A display apparatus comprising:
a display panel configured to display an image;
a panel driver configured to drive the display panel; and
a power supply circuit for supplying power to the display panel and including an output circuit and an output controller, the output circuit including a first switch and a second switch configured to charge or discharge power input through an input terminal thereof to output a power output through an output terminal thereof, and the output controller including a driving circuit configured to control charging or discharging of the output circuit,
wherein the driving circuit is configured to sense an LX node voltage of the output circuit to determine whether at least one of a first body diode included in the first switch or a second body diode included in the second switch is turned on or not, and based thereon, control a dead time corresponding to one of the first switch or the second switch.

2. The display apparatus of claim 1, wherein the driving circuit comprises a dead time controller configured to control the dead time corresponding to one of the first switch or the second switch, based on the LX node voltage sensed from the output circuit, a reference voltage, and a switch control reference signal output from a control circuit of the driving circuit.

3. The display apparatus of claim 2, wherein the dead time controller comprises:
a first body diode sensing circuit configured to output a first sensing result value corresponding to a turn-on time of the first body diode;
a second body diode sensing circuit configured to output a second sensing result value corresponding to a turn-on time of the second body diode;
a first AND gate configured to output a first AND operation value, based on a signal for determining a turn-on or turn-off state of the first body diode and a second switch control reference signal output from the control circuit of the driving circuit;
a second AND gate configured to output a second AND operation value, based on a signal for determining a turn-on or turn-off state of the second body diode and a first switch control reference signal output from the control circuit of the driving circuit;
a third AND gate configured to output a third AND operation value, based on a signal for determining the turn-on or turn-off state of the second body diode and the second switch control reference signal output from the control circuit of the driving circuit;
a first OR gate configured to output a first OR operation value, based on the first AND operation value output from the first AND gate and the third AND operation value output from the third AND gate;
a counter circuit configured to output a counter result value for determining whether there is a time corresponding to a zero current, based on a signal for controlling the first switch and the second switch;
a delay circuit configured to delay, for a time period, the counter result value output from the counter circuit to output a delayed counter result value; and
a second OR gate configured to output a second OR operation value, based on the second AND operation value output from the second AND gate and a delay value output from the delay circuit connected to an output terminal of the counter circuit.

4. The display apparatus of claim 3, wherein the dead time controller comprises:
a first body diode sensing circuit including an inverting terminal connected to the LX node of the output circuit and a noninverting terminal connected to a first reference voltage terminal;
a second body diode sensing circuit including an inverting terminal connected to the LX node of the output circuit and a noninverting terminal connected to a second reference voltage terminal;
a first AND gate including a first input terminal connected to an output terminal of the first body diode sensing circuit and a second input terminal connected to a control circuit of the driving circuit;
a second AND gate including a first input terminal connected to an output terminal of the second body diode sensing circuit and a second input terminal connected to the control circuit of the driving circuit;
a third AND gate including a first input terminal connected to an output terminal of the second AND gate and a second input terminal connected to the control circuit of the driving circuit;
a first OR gate including a first input terminal connected to an output terminal of the first AND gate and a second input terminal connected to an output terminal of the third AND gate;
a counter circuit including a first input terminal connected to an output terminal of the first OR gate and a second input terminal connected to an output terminal of the second OR gate; and
a second OR gate including a first input terminal connected to an output terminal of the second AND gate and a second input terminal connected to the delay circuit connected to an output terminal of the counter circuit.

5. The display apparatus of claim 4, wherein the first reference voltage terminal is configured to provide a first reference voltage obtained by summating a voltage of the input terminal of the output circuit and a first voltage which is lower than a forward voltage value of the first body diode, and
the second reference voltage terminal configured to provide a second reference voltage which is lower than a forward voltage value of the second body diode.

6. The display apparatus of claim 2, wherein the dead time controller comprises:
a first body diode sensing circuit configured to output a first sensing result value corresponding to a turn-on time of the first body diode;
a second body diode sensing circuit configured to output a second sensing result value corresponding to a turn-on time of the second body diode;
a first AND gate configured to output a first AND operation value, based on a signal for determining the turn-on or turn-off state of the first body diode and a second switch control reference signal output from the control circuit of the driving circuit;
a second AND gate configured to output a second AND operation value, based on a signal for determining the turn-on or turn-off state of the second body diode and a first switch control reference signal output from the control circuit of the driving circuit;
a third AND gate configured to output a third AND operation value, based on a signal for determining the turn-on or turn-off state of the second body diode and the second switch control reference signal output from the control circuit of the driving circuit;
a counter circuit configured to output a counter result value for determining whether there is a time corresponding to a zero current, based on a signal for controlling the first switch and the second switch;
a delay circuit configured to delay, for a certain time, the counter result value output from the counter circuit to output a delayed counter result value; and
a first OR gate configured to output a first OR operation value, based on the first AND operation value output from the first AND gate, the third AND operation value output from the third AND gate, and a delay value output from the delay circuit connected to an output terminal of the counter circuit.

7. The display apparatus of claim 3, wherein the dead time controller comprises:
a first body diode sensing circuit including an inverting terminal connected to the LX node of the output circuit and a noninverting terminal connected to a first reference voltage terminal;
a second body diode sensing circuit including an inverting terminal connected to the LX node of the output circuit and a noninverting terminal connected to a second reference voltage terminal;
a first AND gate including a first input terminal connected to an output terminal of the first body diode sensing circuit and a second input terminal connected to a control circuit of the driving circuit;
a second AND gate including a first input terminal connected to an output terminal of the second body diode sensing circuit and a second input terminal connected to the control circuit of the driving circuit;
a third AND gate including a first input terminal connected to an output terminal of the second AND gate and a second input terminal connected to the control circuit of the driving circuit;
a counter circuit including a first input terminal connected to an output terminal of the first OR gate and a second input terminal connected to an output terminal of the second OR gate; and
a first OR gate including a first input terminal connected to an output terminal of the first AND gate, a second input terminal connected to an output terminal of the third AND gate, and a third input terminal connected to the delay circuit connected to an output terminal of the counter circuit.

8. The display apparatus of claim 7, wherein the first reference voltage terminal is configured to provide a first reference voltage obtained by summating a voltage of the input terminal of the output circuit and a first voltage which is lower than a forward voltage value of the first body diode, and
the second reference voltage terminal is configured to provide a second reference voltage which is lower than a forward voltage value of the second body diode.

9. A power supply comprising:
an output circuit including a first switch and a second switch configured to charge or discharge power input through an input terminal thereof to output a power output through an output terminal thereof; and
an output controller including a driving circuit configured to control charging or discharging of the output circuit,
wherein the driving circuit is configured to sense an LX node voltage of the output circuit to determine whether at least one of a first body diode included in the first switch or a second body diode included in the second switch is turned on or not, and based thereon, control a dead time corresponding to one of the first switch or the second switch.

10. The power supply of claim 9, wherein the driving circuit comprises a dead time controller configured to control the dead time corresponding to one of the first switch or the second switch, based on the LX node voltage sensed from the output circuit, a reference voltage, and a switch control reference signal output from a control circuit of the driving circuit.

11. The power supply of claim 10, wherein the dead time controller comprises:
a first body diode sensing circuit configured to output a first sensing result value corresponding to a turn-on time of the first body diode;
a second body diode sensing circuit configured to output a second sensing result value corresponding to a turn-on time of the second body diode;
a first AND gate configured to output a first AND operation value, based on a signal for determining a turn-on or turn-off state of the first body diode and a second switch control reference signal output from the control circuit of the driving circuit;
a second AND gate configured to output a second AND operation value, based on a signal for determining a turn-on or turn-off state of the second body diode and a first switch control reference signal output from the control circuit of the driving circuit;
a third AND gate configured to output a third AND operation value, based on a signal for determining the turn-on or turn-off state of the second body diode and the second switch control reference signal output from the control circuit of the driving circuit;
a first OR gate configured to output a first OR operation value, based on the first AND operation value output from the first AND gate and the third AND operation value output from the third AND gate;
a counter circuit configured to output a counter result value for determining whether there is a time corresponding to a zero current, based on a signal for controlling the first switch and the second switch;
a delay circuit configured to delay, for a time period, the counter result value output from the counter circuit to output a delayed counter result value; and
a second OR gate configured to output a second OR operation value, based on the second AND operation value output from the second AND gate and a delay value output from the delay circuit connected to an output terminal of the counter circuit.

12. The power supply of claim 9, wherein the dead time controller comprises:
a first body diode sensing circuit configured to output a first sensing result value corresponding to a turn-on time of the first body diode;
a second body diode sensing circuit configured to output a second sensing result value corresponding to a turn-on time of the second body diode;
a first AND gate configured to output a first AND operation value, based on a signal for determining the turn-on/off of the first body diode and a second switch control reference signal output from the control circuit of the driving circuit;
a second AND gate configured to output a second AND operation value, based on a signal for determining the turn-on/off of the second body diode and a first switch control reference signal output from the control circuit of the driving circuit;
a third AND gate configured to output a third AND operation value, based on a signal for determining the turn-on/off of the second body diode and the second switch control reference signal output from the control circuit of the driving circuit;
a counter circuit configured to output a counter result value for determining whether there is a time corresponding to a zero current, based on a signal for controlling the first switch and the second switch;
a delay circuit configured to delay, for a certain time, the counter result value output from the counter circuit to output a delayed counter result value; and
a first OR gate configured to output a first OR operation value, based on the first AND operation value output from the first AND gate, the third AND operation value output from the third AND gate, and a delay value output from the delay circuit connected to an output terminal of the counter circuit.

13. A display apparatus comprising:
a display panel configured to display an image; and
a power supply circuit for supplying power to the display panel, the power supply circuit including an output circuit and an output controller, the output circuit including a first switch and a second switch connected in series between an input terminal and a ground terminal, a node between the first switch and the second switch being connected to an output terminal through an inductor, and the output controller configured to sense an inductor voltage of the inductor and control a dead time state of one of the first switch or the second switch based on the inductor voltage sensed.

14. The display apparatus of claim 13, wherein the output controller is configured to:
determine whether at least one of a first body diode included in the first switch or a second body diode included in the second switch is turned on based on the inductor voltage sensed; and
control the dead time state of the one of the first switch or the second switch based on a result of determining whether at least one of the first body diode included in the first switch or the second body diode included in the second switch is turned on.

15. The display apparatus of claim 14, wherein in a case that the power supply circuit operates in a first mode, and in response to determining that the second body diode included in the second switch is on a turn-on state, the output controller is configured to turn on the first switch or the second switch to end a dead time state of the first switch or the second switch.

16. The display apparatus of claim 14, wherein in a case the power supply circuit operates in a second mode, and in response to determining that the first body diode included in the first switch is on a turn-on state, the output controller is configured to turn on the first switch to end a dead time state of the first switch.

17. The display apparatus of claim 14, wherein in a case the power supply circuit operates in a second mode, and in response to determining that the second body diode included in the second switch is on a turn-on state, the output controller is configured to turn on the second switch to end a dead time state of the second switch.

18. The display apparatus of claim 14, wherein in a case the power supply circuit operates in a second mode and the first switch is turned off, in response to determining that the second body diode included in the second switch is in a turn-off state, the output controller is configured to turn on the second switch after a fixed dead time.

19. The display apparatus of claim 13, wherein the output controller includes a first output control circuit and a second output control circuit, the first output control circuit configured to control an operation state of the second output control circuit based on a current and a voltage at the output terminal of the output circuit, and the second output control circuit configured to generate a first switch control signal and a second switch control signal for controlling switching timing of each of the first switch and the second switch, based on a signal output from the first output control circuit.

20. The display apparatus of claim 19, wherein the second output control circuit is configured to forcibly end a dead time state of each of the first switch or the second switch based on a current and a voltage at the input terminal and the inductor voltage.
